(19) United States
(12) Patent Application Publication
(10) Pub. No.: US 2023/0308113 A1
(43) Pub. Date: Sep. 28, 2023

(54) REDUCED LOGIC CONVERSION OF BINARY INTEGERS TO BINARY CODED DECIMALS

(71) Applicant: INTERNATIONAL BUSINESS MACHINES CORPORATION, Armonk, NY (US)

(72) Inventors: KERSTIN CLAUDIA SCHELM, STUTTGART (DE); PETRA LEBER, EHNINGEN (DE); STEFAN PAYER, STUTTGART (DE); CEDRIC LICHTENAU, STUTTGART (DE); MICHAEL KLEIN, SCHOENAICH (DE)

(21) Appl. No.: 17/704,674

(22) Filed: Mar. 25, 2022

(51) Int. Cl. H03M 7/14; G06F 7/491; G06F 5/01; H03K 19/20

(52) U.S. Cl. CPC H03M 7/14; G06F 7/491; G06F 5/01; H03K 19/20

(57) ABSTRACT

Reduced logic conversion of binary integers to binary coded decimals, including: generating, from an input binary integer, an intermediate value comprising all zero digits encoded in an intermediate format; until each bit of the input binary integer has been shifted into the intermediate value: shifting a bit of the input binary integer into the intermediate value; doubling the intermediate value; converting the intermediate value to a binary encoded decimal output; and wherein the intermediate format comprises, for each digit of the intermediate value, a plurality of bits corresponding to a plurality of even weights, a first bit corresponding to a one weight, and a second bit corresponding to an inverse of the one weight.

### BACKGROUND

### Field of the Invention

The field of the invention is data processing, or, more specifically, methods, apparatus, and products for reduced logic conversion of binary integers to binary coded decimals.

### Description of Related Art

The development of the EDVAC computer system of 1948 is often cited as the beginning of the computer era. Since that time, computer systems have evolved into extremely complicated devices. Today's computers are much more sophisticated than early systems such as the EDVAC. Computer systems typically include a combination of hardware and software components, application programs, operating systems, processors, buses, memory, input/output devices, and so on. As advances in semiconductor processing and computer architecture push the performance of the computer higher and higher, more sophisticated computer software has evolved to take advantage of the higher performance of the hardware, resulting in computer systems today that are much more powerful than just a few years ago.

In programming languages such as COBOL, numbers may be encoded in various formats, such as hexadecimal, binary integers, and binary coded decimal. Some operations require numbers to be converted from one format to another. As an example, a binary integer may be converted to binary coded decimal for display in a human-readable format.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 shows a block diagram of an example logic flow for reduced logic conversion of binary integers to binary coded decimals according to some embodiments of the present disclosure.

FIG. 2 shows a table of an intermediate digit encoding format for converting binary integers to binary coded decimals according to embodiments known in the art.

FIG. 3A shows a multiplexer for converting binary integers to binary coded decimals according to embodiments known in the art.

FIG. 3B shows doubler logic for converting binary integers to binary coded decimals according to embodiments known in the art.

FIG. 4 shows a table for an intermediate digit encoding format for reduced logic conversion of binary integers to binary coded decimals according to some embodiments of the present disclosure.

FIG. 5 an example doubler logic for reduced logic conversion of binary integers to binary coded decimals according to some embodiments of the present disclosure.

FIG. 6A an example carrier logic for reduced logic conversion of binary integers to binary coded decimals according to some embodiments of the present disclosure.

FIG. 6B an example inverse carrier logic for reduced logic conversion of binary integers to binary coded decimals according to some embodiments of the present disclosure.

FIG. 7 shows a block diagram of an example computer for reduced logic conversion of binary integers to binary coded decimals according to some embodiments of the present disclosure.

FIG. 8 shows a flowchart of an example method for reduced logic conversion of binary integers to binary coded decimals according to some embodiments of the present disclosure.

### DETAILED DESCRIPTION

In programming languages such as COBOL, numbers may be encoded in various formats, such as hexadecimal, binary integers, and binary coded decimal. Some operations require numbers to be converted from one format to another. As an example, a binary integer may be converted to binary coded decimal for display in a human-readable format.

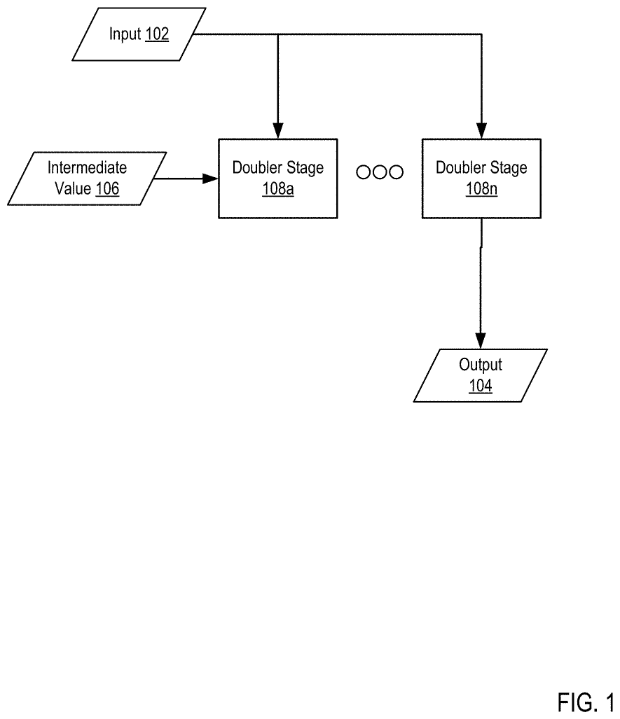

To this end, exemplary methods, apparatus, and products for reduced logic conversion of binary integers to binary coded decimals in accordance with the present invention are described with reference to the accompanying drawings, beginning with FIG. 1. FIG. 1 sets forth an example process flow for reduced logic conversion of binary integers to binary coded decimals according to some embodiments of the present disclosure. The example process flow of FIG. 1 may be implemented, for example, in a chip or other semiconductor device. Such a chip or semiconductor device may be included in a device or apparatus such as a server, personal computer, mobile device, set-top box, and the like.

As shown in FIG. 1, an input 102 encoded as a binary integer is converted to an output 104 encoded as a binary coded decimal value. Accordingly, the input 102 includes a plurality of bits, with each bit corresponding to a particular power of two. In other words, for an n-bit binary integer, each bit corresponds to a particular power of two from 2′ to 2°. As the output 104 is a binary coded decimal value, the output 104 includes a plurality of digits, with each digit being expressed using a binary encoding of numbers zero through nine. In other word, each digit of the output 104 may be expressed using at least four bits used to encode the corresponding zero-through-nine digit.

In order to convert the input 102 binary integer to a binary coded decimal output 104, an intermediate value 106 is generated. The intermediate value 106 includes multiple digits each equal to zero. Each digit in the intermediate value 106 is encoded using a plurality of bits and using an intermediate format to be described in further detail below. As shown, the logic flow of FIG. 1 includes multiple doubling stages 108a-n. At each doubling stage, a most significant bit of the input 102 is shifted into the intermediate value 106. That is, the bits of the intermediate value 106 is shifted left and a most significant bit of the input 102 yet to be shifted in is appended to the intermediate value 106 as a least significant bit. The intermediate value 106 is then doubled as shown in a doubling stage 108a-n. As the logic flow includes multiple doubler stages 108a-n, the shifting of a bit from the input 102 and the doubling of the intermediate value 106 may be performed multiple times within a same clock cycle.

A bit from the input 102 is shifted into the intermediate value 106 and the intermediate value 106 is doubled for each bit in the input 102 until each bit of the input 102 has been shifted into the intermediate value 106 and a doubling operation has been performed. Each digit of the resulting intermediate value 106 is then converted to a corresponding binary coded decimal digit of the output 104.

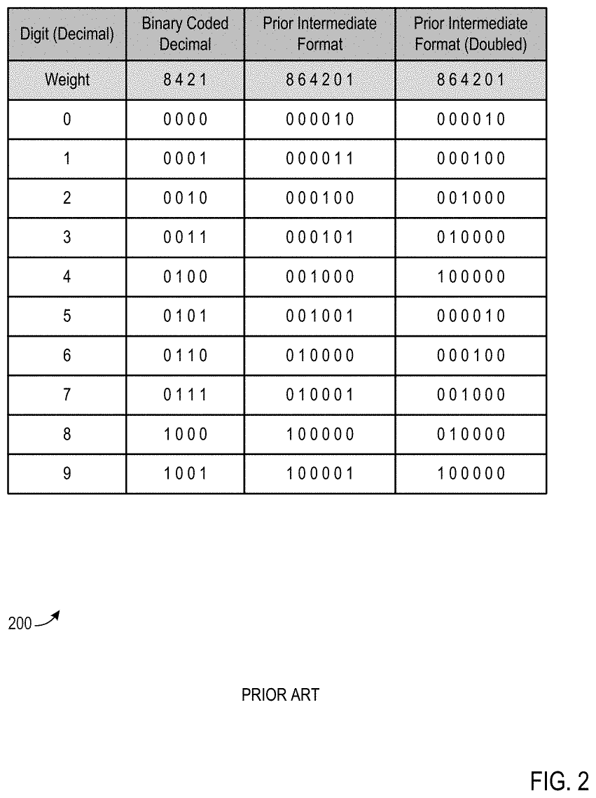

Existing solutions for converting binary integers to binary coded decimal values use an approach similar to that of FIG. 1 whereby bits are repeatedly shifted into an intermediate value 106 and the intermediate value 106 is doubled, eventually being converted to the binary coded decimal output 104. In contrast to the embodiments of the present disclosure, the intermediate format of existing solutions may be described using the table 200 of FIG. 2. The first column of the table 200 shows each possible binary coded digit zero through nine. In the second column, the binary coded decimal encodings of each digit is shown for reference.

The third column of the table 200 shows the encoding of each digit using the prior intermediate format of existing solutions. In the prior intermediate format, each digit is encode using six bits. The five most significant bits of the prior intermediate format each correspond to a particular even numbered weight, from eight to zero in descending order. The sixth most significant bit corresponds to a weight of one. In order to calculate a particular digit, the weights having their corresponding bit set to one are added together. As an example, in order to calculate the digit three, the bits for weights two and one are set. As another example, in order to calculate the digit seven, the bits for weights six and one are set. Using the prior intermediate format, at least one of the five most significant bits corresponding to the even umbered weights must be set to one. Accordingly, the encoding for the digit zero has the bit for the zero weight set and the encoding for the digit one has the zero and one weights set.

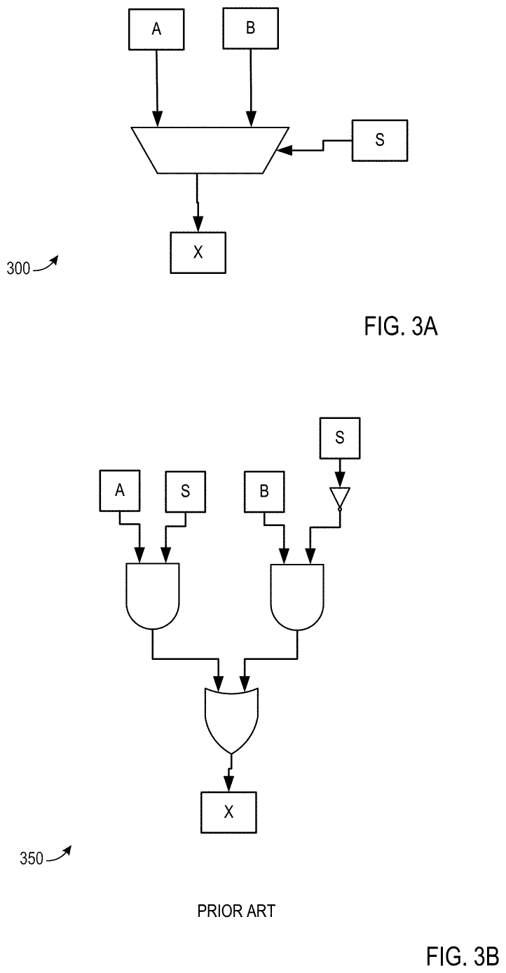

The fourth column of the table 200 shows the doubled encoding of the corresponding digit using the prior intermediate format. For example, for the digit three, the fourth column shows the encoding for the doubled value of six. Though not shown, the doubling of digits five through nine would result in a carry bit that would be added into an adjacent more significant digit. As is clear from the table 200, the value of each bit of a doubled digit for weights eight through two may be expressed by selecting one of a pair of bit values from the original encoding under the prior intermediate format and selected based on the value of the bit for the one weight. This is shown using the multiplexer 300 of FIG. 3A, where any bit value X of a doubled digit may be determined by selecting either bit value A or bit value B from the undoubled digit based on a selection bit S, where the S corresponds to the bit value of the one weight.

As an example, for any doubled digit, the bit value for the eight weight may be selected as either the bit value of the eight weight or the four weight from the undoubled digit, selected based on the bit value of the one weight. In other words, according to FIG. 3A, bit value X would correspond to the eight weight of the doubled digit, bit value A would correspond to the eight weight of the undoubled digit, bit value B would correspond to the four weight of the undoubled digit, and bit value S would correspond to the one weight of the undoubled digit. As another example, for any doubled digit, the bit value for the six weight may be selected as either the bit value of the two weight or the eight weight from the undoubled digit, selected based on the bit value of the one weight. In other words, according to FIG. 3A, bit value X would correspond to the six weight of the doubled digit, bit value A would correspond to the two weight of the undoubled digit, bit value B would correspond to the eight weight of the undoubled digit, and bit value S would correspond to the one weight of the undoubled digit.

The multiplexer 300 of FIG. 3A may be implemented using the doubler logic 350 of FIG. 3B. As shown in FIG. 3B, undoubled digit bit values A and S are provide to a first AND gate. Undoubled digit bit value B and the output of an inverter accepting as input the undoubled digit bit value for S are provided to a second AND gate. The outputs of the AND gates are then provided to an OR gate to generate the doubled digit bit value X. One skilled in the art will appreciate that a chip or device implementing the doubler logic 350 would include multiple doubler logics 350 each corresponding to a particular bit of the intermediate value being doubled.

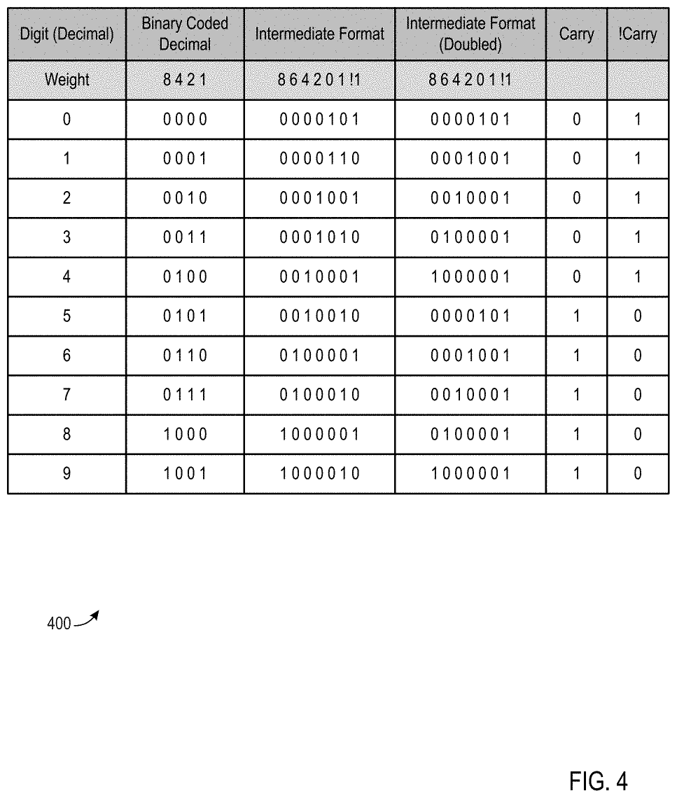

In contrast to the existing solutions shown in FIGS. 2, 3A, and 3B, reduced logic conversion of binary integers to binary coded decimals is implemented using the logic flow of FIG. 1 and an intermediate format described in table 400 of FIG. 4. The intermediate format of the table 400 is similar to that of the prior intermediate format of the table 200 except that the intermediate format of the table 400 uses an additional seventh bit for each digit. This seventh bit (e.g., the least significant bit) of each digit encodes the inverse of the bit value for the one weight. The doubled digits for the intermediate format are shown in the fourth column of the table 200. The fifth and sixth columns show the value of a carry and inverse carry bit for a doubling operation, which may be combined into a more significant adjacent digit during the doubling process.

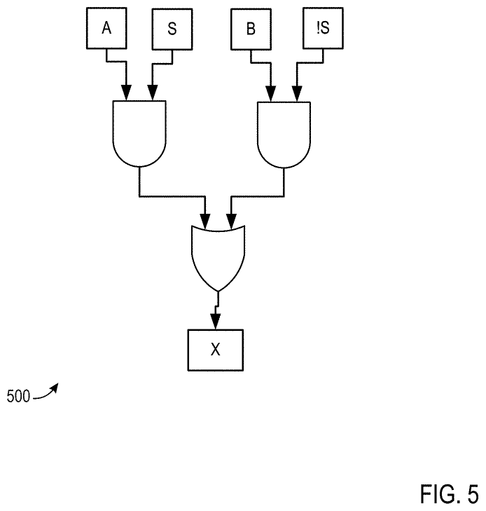

In further contrast to the existing solutions shown in FIGS. 2, 3A, and 3B, the bit values for the weights eight through two of a doubled digit may be expressed using the doubler logic 500 of FIG. 5. Here, instead of the bit value S (e.g., the bit value for the one weight) being passed through an inverter before being provided to an AND gate, the bit value for the inverse S weight (e.g., the bit value for the inverse of the one weight) is provided directly to the AND gate. Accordingly, fewer logic gates are required to perform a doubling operation for an intermediate value, allowing more doubling operations to be performed per clock cycle, improving performance. One skilled in the art will appreciate that a chip or device implementing the doubler logic 500 would include multiple doubler logics 500 each corresponding to a particular bit of the intermediate value 106 being doubled.

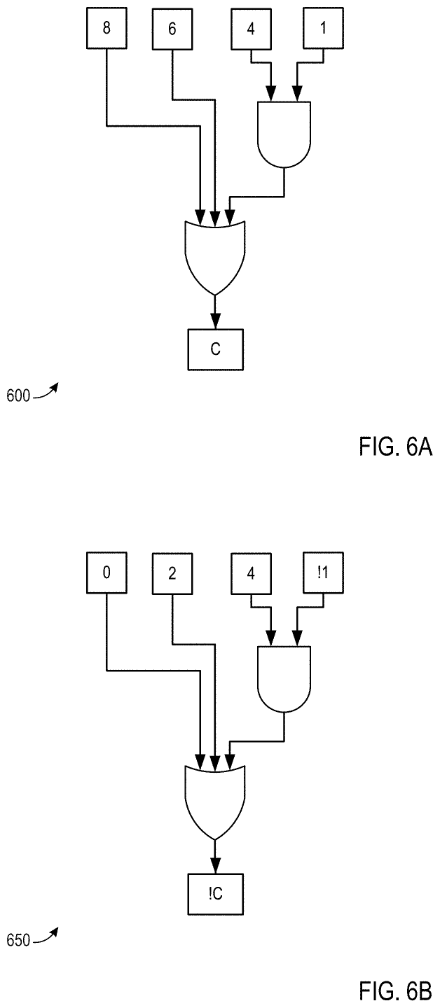

FIG. 6A shows a carrier logic 600 for calculating the value of a carry bit when performing a doubling operation of a digit encoded under the intermediate format of FIG. 4. Here, the bit values for the eight and six weights are provided to an OR gate. The bit values of the four weight and one weight are provided to an AND gate, with the output of the AND gate also provided to the OR gate. The output of the OR gate is the value of a carry bit for the doubled digit.

FIG. 6B shows an inverse carrier logic 650 for calculating the value of an inverse carry bit when performing a doubling operation of a digit encoded under the intermediate format of FIG. 4. Here, the bit values for the zero and two weights are provided to an OR gate. The bit values of the four weight and inverse one weight are provided to an AND gate, with the output of the AND gate also provided to the OR gate. The output of the OR gate is the value of an inverse carry bit for the doubled digit.

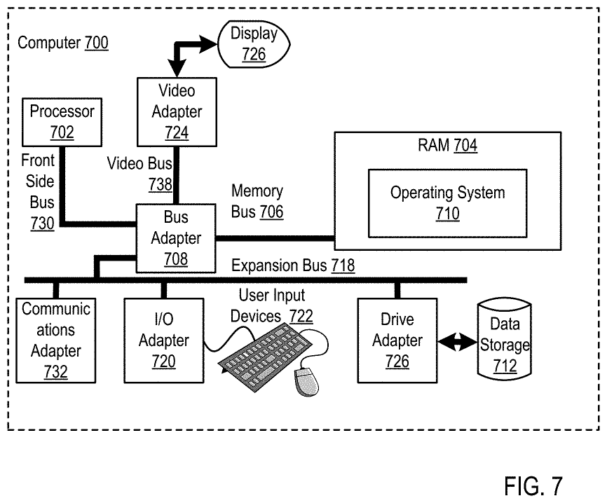

Reduced logic conversion of binary integers to binary coded decimals in accordance with the present application is generally implemented with computers, that is, with automated computing machinery. For further explanation, therefore, FIG. 7 sets forth a block diagram of computing machinery including an exemplary computer 700 configured for reduced logic conversion of binary integers to binary coded decimals according to certain embodiments. The computer 700 of FIG. 7 includes at least one computer processor 702 or ‘CPU’ as well as random access memory 704 (RAM′) which is connected through a high speed memory bus 706 and bus adapter 708 to processor 702 and to other components of the computer 700.

Stored in RAM 704 is an operating system 710. Operating systems useful in computers configured for reduced logic conversion of binary integers to binary coded decimals according to certain embodiments include UNIX™, Linux™, Microsoft Windows™, and others as will occur to those of skill in the art. The operating system 710 in the example of FIG. 7 is shown in RAM 704, but many components of such software typically are stored in non-volatile memory also, such as, for example, on data storage 712, such as a disk drive.

The computer 700 of FIG. 7 includes disk drive adapter 716 coupled through expansion bus 718 and bus adapter 708 to processor 702 and other components of the computer 700. Disk drive adapter 716 connects non-volatile data storage to the computer 700 in the form of data storage 712. Disk drive adapters useful in computers configured for reduced logic conversion of binary integers to binary coded decimals according to certain embodiments include Integrated Drive Electronics (IDE′) adapters, Small Computer System Interface (SCSI′) adapters, and others as will occur to those of skill in the art. In some embodiments, non-volatile computer memory is implemented as an optical disk drive, electrically erasable programmable read-only memory (so-called ‘EEPROM’ or ‘Flash’ memory), RAM drives, and so on, as will occur to those of skill in the art.

The example computer 700 of FIG. 7 includes one or more input/output (I/O′) adapters 720. I/O adapters implement user-oriented input/output through, for example, software drivers and computer hardware for controlling output to display devices such as computer display screens, as well as user input from user input devices 722 such as keyboards and mice. The example computer 700 of FIG. 7 includes a video adapter 724, which is an example of an I/O adapter specially designed for graphic output to a display device 726 such as a display screen or computer monitor. Video adapter 724 is connected to processor 702 through a high speed video bus 728, bus adapter 708, and the front side bus 730, which is also a high speed bus.

The exemplary computer 700 of FIG. 7 includes a communications adapter 732 for data communications with other computers and for data communications with a data communications network. Such data communications are carried out serially through RS-232 connections, through external buses such as a Universal Serial Bus (‘USB’), through data communications networks such as IP data communications networks, and/or in other ways as will occur to those of skill in the art. Communications adapters implement the hardware level of data communications through which one computer sends data communications to another computer, directly or through a data communications network. Examples of communications adapters useful in computers configured for reduced logic conversion of binary integers to binary coded decimals according to certain embodiments include modems for wired dial-up communications, Ethernet (IEEE 802.3) adapters for wired data communications, and 802.11 adapters for wireless data communications.

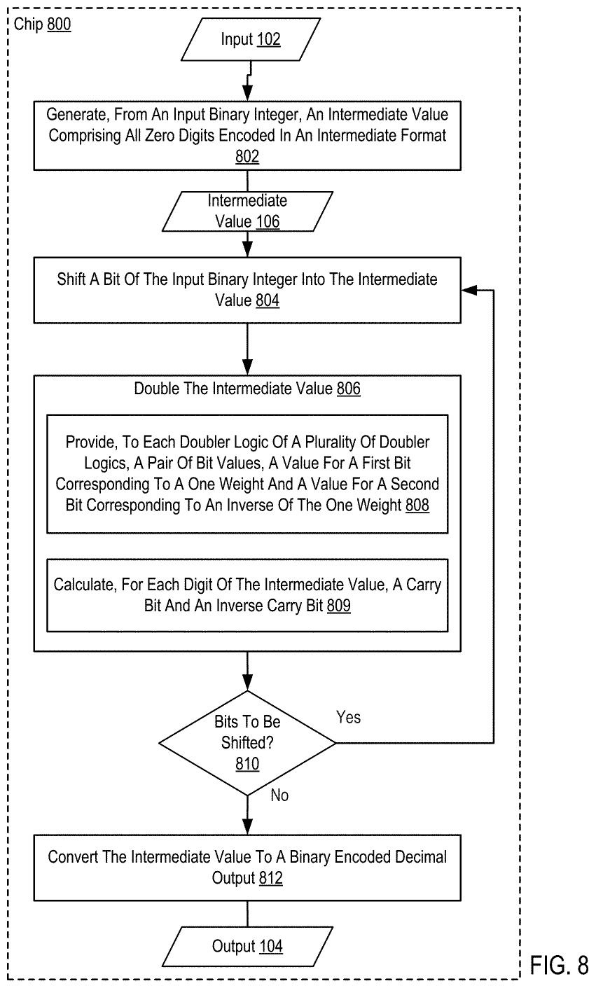

For further explanation, FIG. 8 shows a flowchart of an example method for reduced logic conversion of binary integers to binary coded decimals according to some embodiments of the present disclosure. The method of FIG. 8 may be performed, for example, in a chip 800 or another semiconductor device as can be appreciated. The method of FIG. 8 may also be performed in a device or apparatus such as a computing device including a chip 800 or semiconductor device as described herein.

The method of FIG. 8 includes generating 802, from an input binary integer (shown as the input 102), an intermediate value 106 comprising all zero digits encode using an intermediate format. The intermediate format includes an intermediate format as described in the table 400 of FIG. 4 including a bit for an inverse one weight as a least significant bit in each digit. Each digit of the intermediate value 106 is initially encoded as a zero digit using this intermediate format.

The method of FIG. 8 includes shifting 804 a bit of the input binary integer (e.g., the input 102) into the intermediate value 106. That is, the bits of the intermediate value 106 are shifted left by one and a most significant bit of the input 102 yet to be shifted in is appended to the intermediate value 106 as a least significant bit.

The method of FIG. 8 also includes doubling 806 the intermediate value 106. Thus, each digit of the intermediate value 106 is doubled to generate a new intermediate value 106. In some embodiments, doubling 806 the intermediate value 106 includes providing 808 (e.g., for each digit of the intermediate value 106), each doubler logic 500 of a plurality of doubler logics 500, a pair of bit values of the plurality of bits (e.g., the plurality of bits for each digit), a first bit value corresponding to the one weight and a second bit value corresponding to the inverse of the one weight.

For example, each digit of the doubled intermediate value 106 may correspond to a plurality of doubler logics 500, with each doubler logic 500 configured to calculate a bit value for the weights eight through two of the doubled digit. Accordingly, each doubler logic 500 accepts, as input, a pair of bit values from the undoubled digit used to calculate a particular bit value of the doubled digit. Each doubler logic 500 also accepts, as input, from the undoubled digit, the bit values for the one weight and inverse one weight.

In some embodiments, doubling 806 the intermediate value 106 also includes calculating 809, for each digit of the intermediate value 106, a carry bit and an inverse carry bit (e.g., using carrier logic 600 of FIG. 6A and inverse carrier logic 650 of FIG. 6B). The carrier bit and inverse carry bit for a given doubled digit may then be combined with the doubled digit of a more significant adjacent doubled digit as part of a doubling operation.

At step 810, it is determined if there are bits of the input binary integer (e.g., the input 102) yet to be shifted in. If there are, the process returns to shifting 804 a bit of the input binary integer into the intermediate value 804. Otherwise, once all bits are shifter in, the intermediate value 106 is converted 812 to a binary encoded decimal output 104. That is, each digit of the intermediate value 106 encoded using the intermediate format is converted to a corresponding binary encoded decimal. The output 104 may then be acted upon, for example, to display the output 104 or perform other operations.

In view of the explanations set forth above, readers will recognize that the benefits of reduced logic conversion of binary integers to binary coded decimals according to embodiments of the present invention include improved performance of a computing system by reducing the number of logic gates required to convert a binary integer to a binary coded decimal, increasing the number of doubling stages performed per cycle and improving performance.

Exemplary embodiments of the present invention are described largely in the context of a fully functional computer system for reduced logic conversion of binary integers to binary coded decimals. Readers of skill in the art will recognize, however, that the present invention also may be embodied in a computer program product disposed upon computer readable storage media for use with any suitable data processing system. Such computer readable storage media may be any storage medium for machine-readable information, including magnetic media, optical media, or other suitable media. Examples of such media include magnetic disks in hard drives or diskettes, compact disks for optical drives, magnetic tape, and others as will occur to those of skill in the art. Persons skilled in the art will immediately recognize that any computer system having suitable programming means will be capable of executing the steps of the method of the invention as embodied in a computer program product. Persons skilled in the art will recognize also that, although some of the exemplary embodiments described in this specification are oriented to software installed and executing on computer hardware, nevertheless, alternative embodiments implemented as firmware or as hardware are well within the scope of the present invention.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A method of reduced logic conversion of binary integers to binary coded decimals, the method comprising:
generating, from an input binary integer, an intermediate value comprising all zero digits encoded in an intermediate format;
until each bit of the input binary integer has been shifted into the intermediate value:
shifting a bit of the input binary integer into the intermediate value;
doubling the intermediate value;
converting the intermediate value to a binary encoded decimal output; and
wherein the intermediate format comprises, for each digit of the intermediate value, a plurality of bits corresponding to a plurality of even weights, a first bit corresponding to a one weight, and a second bit corresponding to an inverse of the one weight.

2. The method of claim 1, wherein shifting the bit of the input binary integer and doubling the intermediate value are performed a plurality of times within a same clock cycle.

3. The method of claim 1, wherein the plurality of even weights comprises an eight weight, a six weight, a four weight, a two weight, and a zero weight.

4. The method of claim 1, wherein each bit of the plurality of bits corresponds to a doubler logic of a plurality of doubler logics, and wherein doubling the intermediate value comprises providing, to each doubler logic of the plurality of doubler logics, a pair of bit values of the plurality of bits, a value for the first bit, and a value of the second bit.

5. The method of claim 1, wherein each doubler logic comprises:
a first AND gate accepting, as input, a first bit value from the pair of bit values and the value for the first bit;
a second AND gate accepting, as input, a second bit value from the pair of bit values and the value for the second bit; and
an OR gate accepting, as input, an output from the first AND gate and an output from the second AND gate.

6. The method of claim 1, wherein doubling the intermediate value further comprises calculating, for each digit of the intermediate value, a carry bit and an inverse carry bit.

7. The method of claim 6, wherein the value of the first bit and the value of the second bit for a given digit correspond to the carry bit and the inverse carry bit for an adjacent digit.

8. A chip for reduced logic conversion of binary integers to binary coded decimals, comprising:
generating, from an input binary integer, an intermediate value comprising all zero digits encoded in an intermediate format;
until each bit of the input binary integer has been shifted into the intermediate value:
shifting a bit of the input binary integer into the intermediate value;
doubling the intermediate value;
converting the intermediate value to a binary encoded decimal output; and
wherein the intermediate format comprises, for each digit of the intermediate value, a plurality of bits corresponding to a plurality of even weights, a first bit corresponding to a one weight, and a second bit corresponding to an inverse of the one weight.

9. The chip of claim 8, wherein shifting the bit of the input binary integer and doubling the intermediate value are performed a plurality of times within a same clock cycle.

10. The chip of claim 8, wherein the plurality of even weights comprises an eight weight, a six weight, a four weight, a two weight, and a zero weight.

11. The chip of claim 8, wherein each bit of the plurality of bits corresponds to a doubler logic of a plurality of doubler logics, and wherein doubling the intermediate value comprises providing, to each doubler logic of the plurality of doubler logics, a pair of bit values of the plurality of bits, a value for the first bit, and a value of the second bit.

12. The chip of claim 11, wherein each doubler logic comprises:
a first AND gate accepting, as input, a first bit value from the pair of bit values and the value for the first bit;
a second AND gate accepting, as input, a second bit value from the pair of bit values and the value for the second bit; and
an OR gate accepting, as input, an output from the first AND gate and an output from the second AND gate.

13. The chip of claim 8, wherein doubling the intermediate value further comprises calculating, for each digit of the intermediate value, a carry bit and an inverse carry bit.

14. The chip of claim 13, wherein the value of the first bit and the value of the second bit for a given digit correspond to the carry bit and the inverse carry bit for an adjacent digit.

15. An apparatus for reduced logic conversion of binary integers to binary coded decimals, comprising:
generating, from an input binary integer, an intermediate value comprising all zero digits encoded in an intermediate format;
until each bit of the input binary integer has been shifted into the intermediate value:
shifting a bit of the input binary integer into the intermediate value;
doubling the intermediate value;
converting the intermediate value to a binary encoded decimal output; and
wherein the intermediate format comprises, for each digit of the intermediate value, a plurality of bits corresponding to a plurality of even weights, a first bit corresponding to a one weight, and a second bit corresponding to an inverse of the one weight.

16. The apparatus of claim 15, wherein shifting the bit of the input binary integer and doubling the intermediate value are performed a plurality of times within a same clock cycle.

17. The apparatus of claim 15, wherein the plurality of even weights comprises an eight weight, a six weight, a four weight, a two weight, and a zero weight.

18. The apparatus of claim 15, wherein each bit of the plurality of bits corresponds to a doubler logic of a plurality of doubler logics, and wherein doubling the intermediate value comprises providing, to each doubler logic of the plurality of doubler logics, a pair of bit values of the plurality of bits, a value for the first bit, and a value of the second bit.

19. The apparatus of claim 18, wherein each doubler logic comprises:
a first AND gate accepting, as input, a first bit value from the pair of bit values and the value for the first bit;
a second AND gate accepting, as input, a second bit value from the pair of bit values and the value for the second bit; and
an OR gate accepting, as input, an output from the first AND gate and an output from the second AND gate.

20. The apparatus of claim 15, wherein doubling the intermediate value further comprises calculating, for each digit of the intermediate value, a carry bit and an inverse carry bit.
